(19) United States
(12) Patent Application Publication
(10) Pub. No.: US 2026/0190700 A1
(43) Pub. Date: Jul. 2, 2026

(54) DISPLAY APPARATUS

(71) Applicant: LG Display Co., Ltd., Seoul (KR)

(72) Inventors: Inae CHOI, Paju-si (KR); Sejong SEONG, Paju-si (KR)

(73) Assignee: LG Display Co., Ltd., Seoul (KR)

(21) Appl. No.: 19/352,058

(22) Filed: Oct. 7, 2025

(30) Foreign Application Priority Data
Dec. 30, 2024 (KR) 10-2024-0200171

(51) Int. Cl. H10K 59/131; H10K 59/38; H10K 59/80; H10K 71/00; H10K 102/00

(52) U.S. Cl. CPC H10K 59/131; H10K 59/38; H10K 59/8052; H10K 71/861; H10K 2102/3023; H10K 2102/341

(57) ABSTRACT

A display apparatus includes a substrate having a plurality of pixels, each pixel having a plurality of subpixels. A first non-light emission area is provided on the substrate and positioned within each subpixel, and a second non-light emission area is connected to the first non-light emission area and located between adjacent subpixels of the plurality of subpixels. A light-emission area is arranged adjacent to both the first non-light emission area and the second non-light emission area. A repair portion is disposed in the first non-light emission area to support electrical disconnection in the event of a short circuit. This configuration enables expansion of the light-emission area and enhances light emission efficiency while maintaining repair functionality within the subpixel structure.

### CROSS-REFERENCE TO RELATED APPLICATIONS

This application claims the benefit of the Korean Patent Applications No. 10-2024-0200171 filed on Dec. 30, 2024, which are hereby incorporated by reference as if fully set forth herein.

### BACKGROUND

### Technical Field

The present disclosure relates to a display apparatus displaying images.

### Description of the Related Art

Since an organic light emitting display apparatus has a high response speed and low power consumption and self-emits light without requiring a separate light source unlike a liquid crystal display apparatus, there is no problem in a viewing angle and thus the organic light emitting display apparatus has received attention as a next-generation flat panel display apparatus.

The display apparatus includes a plurality of subpixels, and the plurality of subpixels include a light-emitting element layer provided in a light-emission area. The display apparatus displays an image by emitting light from the light-emitting element layer.

### BRIEF SUMMARY

In conventional display apparatuses, a repair line is typically provided between the light-emission area and a circuit area to prevent the entire light-emission area of each subpixel from becoming non-functional due to a short circuit between lines or electrodes. However, when the repair line is placed within the light-emission area, it reduces the available space for light emission, thereby decreasing light efficiency. As a result, the presence of the repair line imposes limitations on expanding the light-emission area and hinders improvements in light efficiency.

Various embodiments of the display apparatus disclosed herein improve light emission efficiency and repairability by structurally relocating the repair portion to a non-light emission region positioned within each subpixel but outside the active emission areas. This arrangement allows for an increased area dedicated to light emission compared to conventional configurations. Additionally, reflective surfaces are angled within inner and outer non-light emission regions to redirect waveguided light toward the substrate, enabling recovery of light that would otherwise be lost.

The repair portions are further protected by overlying color filters, such as blue filters in white subpixels, which act as laser shields during repair and reduce the risk of damage to the reflective electrode. The repair pads are designed with a width that balances effective laser targeting and minimal interference with light output. Subpixels are formed with multiple light emission regions connected by narrow bridge portions that can be selectively severed if defects occur. This structure allows for partial subpixel operation following localized damage, and may be supplemented by welding lines that reroute electrical paths, thereby supporting improved repair flexibility and light emission performance.

For example, an aspect of the present disclosure is directed to providing a display apparatus in which a size (or area) of a light-emission area can be expanded.

An aspect of the present disclosure is directed to providing a display apparatus capable of improving light efficiency.

An aspect of the present disclosure is directed to providing a display apparatus in which the light extraction efficiency of light emitted from a light-emitting element layer can be maximized.

An aspect of the present disclosure is directed to providing a display apparatus in which the overall power consumption can be reduced through light extraction in a non-light emission area.

The problems to be solved by embodiments of the present disclosure are not limited to those mentioned above, and other problems not mentioned above will be apparent to those skilled in the art to which the technical ideas of the present disclosure belong from the following descriptions.

A display apparatus comprises a substrate including a plurality of pixels having a plurality of subpixels; a first non-light emission area provided on the substrate and located inside each of the plurality of subpixels; a second non-light emission area connected to the first non-light emission area and located between the plurality of subpixels; a light-emission area adjacent to each of the first non-light emission area and the second non-light emission area; and a repair portion disposed in the first non-light emission area.

The technical benefits of the present disclosure are not limited to the above-mentioned benefits, and other benefits, which are not mentioned above, can be clearly understood by those skilled in the art from the following descriptions.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic plan view of a display apparatus according to one embodiment of the present disclosure.

FIG. 2 is a schematic plan view of one pixel shown in FIG. 1.

FIG. 3 is a plan view schematically showing a repair portion and branch lines in FIG. 2.

FIG. 4 is a schematic plan view showing one subpixel of a display apparatus according to one embodiment of the present disclosure and one subpixel of a display apparatus according to a comparative example.

FIG. 5 is a schematic cross-sectional view taken along a line I-I′ shown in FIG. 3.

FIG. 6 is a schematic cross-sectional view taken along a line II-II′ shown in FIG. 3.

FIG. 7 is a schematic cross-sectional view taken along a line III-III′ shown in FIG. 3.

FIG. 8 is a schematic cross-sectional view taken along a line IV-IV′ shown in FIG. 3.

FIG. 9 is a schematic cross-sectional view taken along a line V-V′ shown in FIG. 3.

FIG. 10 is a schematic plan view illustrating two pixels of a display apparatus according to one embodiment of the present disclosure.

### DETAILED DESCRIPTION

Reference will now be made in detail to the embodiments of the present disclosure, examples of which are (shown in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings.

The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted.

In a case where ‘comprise,’ ‘have,’ and ‘include’ described in the present disclosure are used, another part may be added unless ‘only˜’ is used. The terms of a singular form may include plural forms unless referred to the contrary.

In construing an element, the element is construed as including an error range although there is no explicit description. In describing a position relationship, for example, when a position relation between two parts is described as ‘on˜,’ ‘over˜,’ ‘under˜,’ and ‘next˜,’ one or more other parts may be disposed between the two parts unless ‘just’ or ‘direct’ is used.

In describing a temporal relationship, for example, when the temporal order is described as “after,” “subsequent,” “next,” and “before,” a case which is not continuous may be included, unless “just” or “direct” is used.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

It will be understood that, although the terms “first,” “second,” etc., may be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction,” “Y-axis direction” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items.

For example, the meaning of “at least one of a first item, a second item and a third item” denotes the combination of all items proposed from two or more of the first item, the second item and the third item as well as the first item, the second item or the third item.

Features of various embodiments of the present disclosure may be partially or overall coupled to or combined with each other and may be variously inter-operated with each other and driven technically as those skilled in the art can sufficiently understand.

The embodiments of the present disclosure may be carried out independently from each other or may be carried out together in co-dependent relationship.

Hereinafter, the preferred embodiments of the present disclosure will be described in detail with reference to the accompanying drawings.

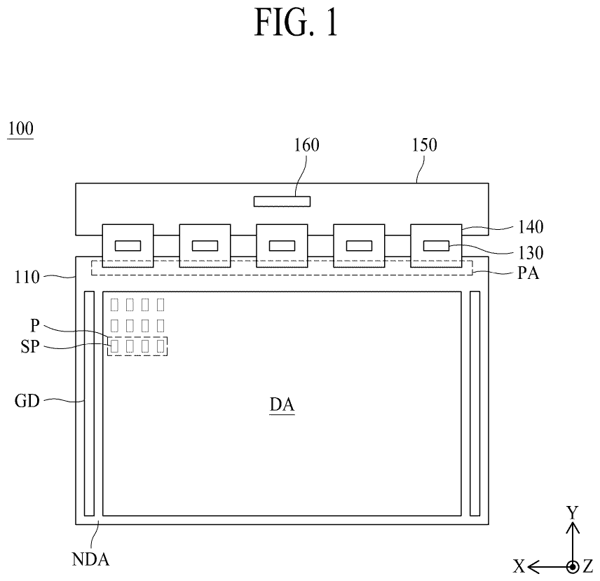

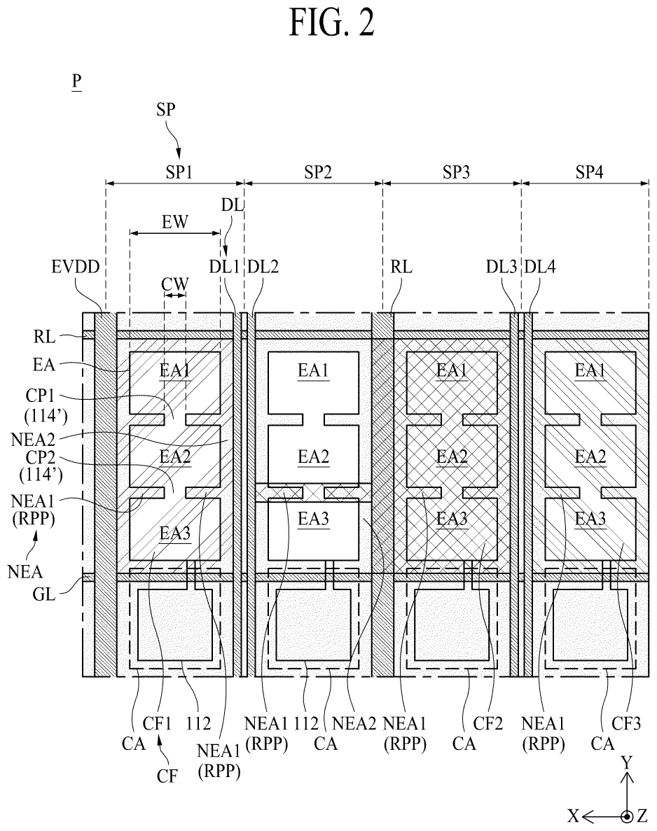

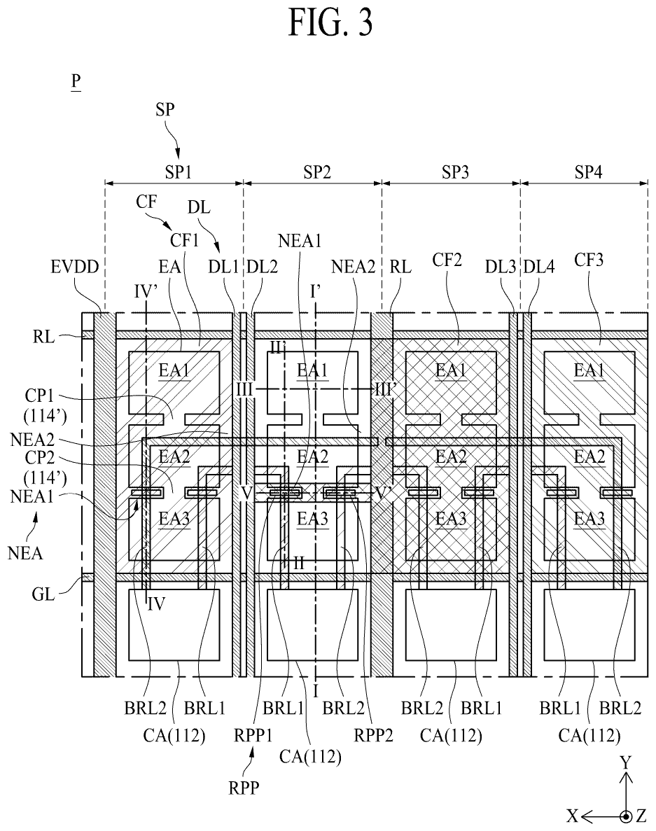

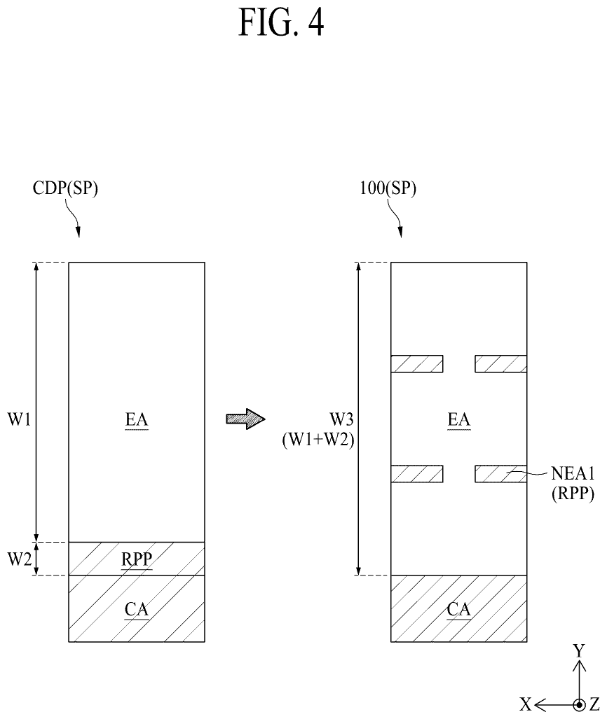

FIG. 1 is a schematic plan view of a display apparatus according to one embodiment of the present disclosure, FIG. 2 is a schematic plan view of one pixel (shown in FIG. 1, FIG. 3 is a plan view schematically showing a repair portion and branch lines in FIG. 2, and FIG. 4 is a schematic plan view showing one subpixel of a display apparatus according to one embodiment of the present disclosure and one subpixel of a display apparatus according to a comparative example.

Hereinafter, a first direction (Y-axis direction) represents a vertical direction based on FIG. 1, a second direction (X-axis direction) represents a horizontal direction based on FIG. 1, and a third direction (Z-axis direction) represents a thickness direction of a display apparatus 100. The first direction (Y-axis direction) may be a direction parallel to a data line DL (shown in FIG. 2). The second direction (X-axis direction) may be a direction parallel to a gate line GL (shown in FIG. 2).

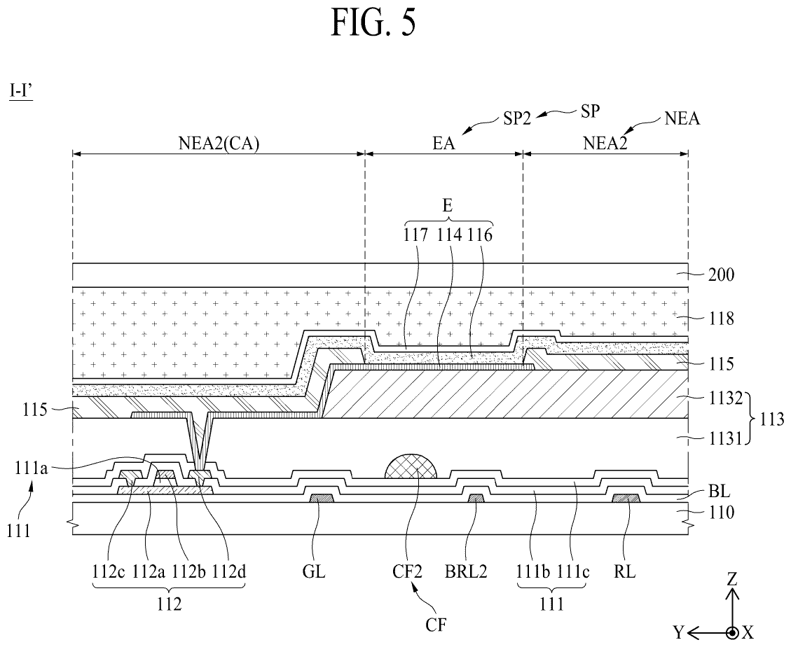

Referring to FIG. 1, a display apparatus 100 according to one embodiment of the present disclosure may include a display panel having a gate driver GD. The display panel may include a substrate 110 and an opposing substrate 200 (shown in FIG. 5) bonded to each other.

The substrate 110 according to one example may include a display area DA in which a plurality of pixels P having a plurality of subpixels SP are arranged, and a non-display area NDA around the display area DA. The substrate 110 may further include a first non-light emission area NEA1, a second non-light emission area NEA2, a light emission area EA, and a repair structure RPP (also referred to as ‘a repair portion RPP’). The first non-light emission area NEA1, the second non-light emission area NEA2, the light emission area EA, and the repair portion RPP may be provided in the display area DA of the substrate 110.

Each of the first non-light emission area NEA1 and the second non-light emission area NEA2 may be an area where light is not emitted. In contrast, the light emission area EA may be an area where light is emitted.

According to one example, the first non-light emission area NEA1 is provided on the substrate 110 and may be provided on an inner side of each of the plurality of sub-pixels SP. For example, as shown in FIG. 2, the first non-light emission area NEA1 may be provided on the inner side of the light emission area EA of each of the plurality of sub-pixels SP (or between the light emission areas EA).

According to one example, each light emission area EA of the plurality of subpixels SP may include a first light emission area EA1, a second light emission area EA2, and a third light emission area EA3. The first light emission area EA1 may be connected to the second light emission area EA2 through a first connecting portion CP1. The second light-emission area EA2 can be connected to the third light-emission area EA3 via a second connecting portion CP2. Each of the first connecting portion CP1 and the second connecting portion CP2 can be a light-emission area EA. As shown in FIG. 2, the first non-light emission area NEA1 according to one example can be arranged between the first light-emission area EA1 and the second light-emission area EA2, and between the second light-emission area EA2 and the third light-emission area EA3.

According to one example, the second non-light emission area NEA2 may be connected to the first non-light emission area NEA1. The second non-light emission area NEA2 may be an area between the plurality of subpixels SP. Accordingly, the first light emission area NEA1 and the second light emission area NEA2 may be provided to surround the light emission area EA. Therefore, the light emission area EA may be provided adjacent to each of the first non-light emission area NEA1 and the second non-light emission area NEA2.

The repair portion RPP is intended to prevent the entire light-emission area EA of each subpixel SP from becoming dark due to a short circuit between the lines (or electrodes) included in the substrate 110.

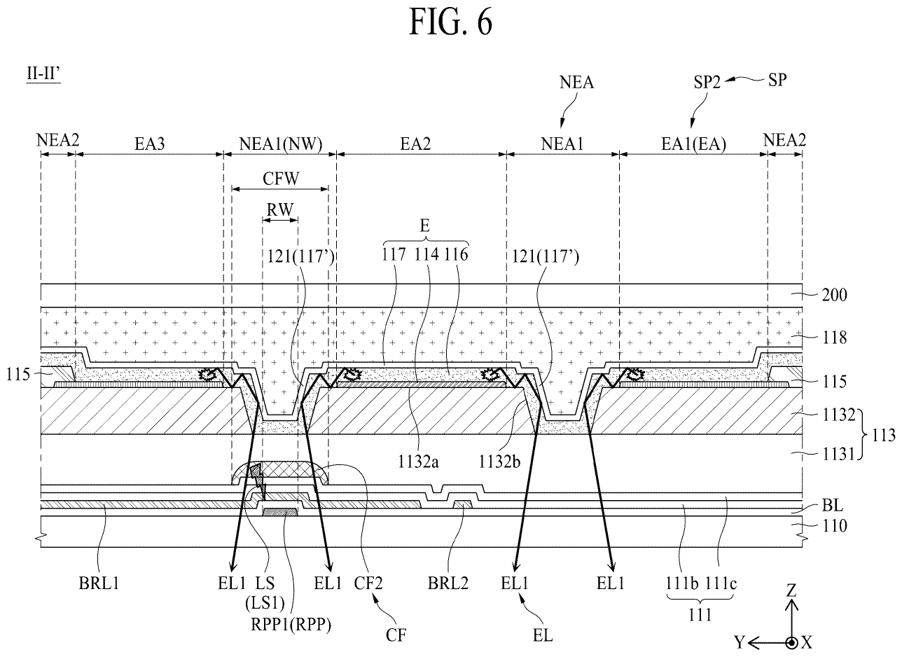

For example, the repair portion RPP can transmit a laser impulse LS (shown in FIG. 6) received from a laser apparatus to a line (e.g., a data branch line BRL1 (shown in FIG. 6)), thereby causing the line (e.g., the data branch line BRL1 (shown in FIG. 6)) on the repair portion RPP to be cut. Accordingly, the display apparatus 100 according to one embodiment of the present disclosure can prevent the entire light-emission area EA of each sub-pixel SP from becoming dark (or unable to be driven or unable to emit light) due to a short circuit between lines (e.g., data lines and scan lines) (or electrodes).

In the display apparatus 100 according to one embodiment of the present disclosure, a repair portion RPP may be provided in the first non-light emission area NEA1.

In the case of a general display apparatus, repair line (or repair portion) is not provided on an inside of each of the plurality of subpixels (or on the inside of the light-emission area). If repair line (or repair portion) is provided on the inside of each of the plurality of subpixels (or on the inside of the light-emission area), a size (or area) of the light-emission area becomes smaller, thus reducing the light efficiency. Therefore, in the case of general display apparatus, the repair line (or repair portion) is arranged on an outside of the light-emission area.

In contrast, the display apparatus 100 according to one embodiment of the present disclosure may have the repair portion RPP provided in the first non-light emission area NEA1 located inside each of the plurality of sub-pixels SP.

For example, as shown in FIG. 4, in the case of a general display apparatus CDP, a repair portion RPP including one subpixel SP is placed between the light-emission area EA and a circuit area CA. Accordingly, in the case of the general display apparatus CDP, a light-emission area EA having a first length W1 (or a first width W1) and a repair portion RPP having a second length W2 (or a second width W2) may be provided on an upper side of the circuit area CA.

In contrast, the display apparatus 100 according to one embodiment of the present disclosure may be provided with the repair portion RPP in the first non-light emission area NEA1 inside each of the plurality of sub-pixels SP, so that the light emission area EA may have a third length W3 (or a third width W3). The third length W3 (or the third width W3) may be a length (or width) that is a sum of the first length W1 (or the first width W1) and the second length W2 (or the second width W2).

Therefore, the display apparatus 100 according to one embodiment of the present disclosure can have an expanded size (or area) of the light-emission area EA compared to the display apparatus CDP according to a comparative example, so that the light efficiency can be further improved.

Meanwhile, in the case of the general display apparatus, if a non-light emission area is provided on the inside of each of the plurality of subpixels, light efficiency may be reduced.

However, since the display apparatus 100 according to one embodiment of the present disclosure is provided with a first reflective portion 121 (shown in FIG. 6) in the first non-light emission area NEA1, light extraction can be achieved through the first reflective portion 121, so that the light efficiency may not be reduced.

As a result, the display apparatus 100 according to one embodiment of the present disclosure may not have the light efficiency reduced due to the first reflective portion 121 in the first non-light emission area NEA1 even when the first non-light emission area NEA1 is arranged inside each of the plurality of sub-pixels SP, and since the size (or area) of the light emission area EA may be expanded by providing the repair portion RPP in the first non-light emission area NEA1, the light efficiency may be improved.

Referring to FIG. 1, a display apparatus 100 according to one embodiment of the present disclosure may include a source drive integrated circuit (Hereinafter referred to as “IC”) 130, a flexible film 140, a circuit board 150, and a timing control portion 160.

The substrate 110 may include a thin film transistor, and may be a transistor array substrate, a lower substrate, a base substrate, or a first substrate. The substrate 110 may be a transparent glass substrate or a transparent plastic substrate.

The opposing substrate 200 may be bonded to the substrate 110 via an adhesive member. For example, the opposing substrate 200 has a smaller size than the substrate 110 and can be bonded to a remaining portion except for a pad portion of the substrate 110. The opposing substrate 200 may be an upper substrate, a second substrate, or an encapsulation substrate.

The gate driver GD supplies gate signals to the gate lines in accordance with the gate control signal input from the timing control portion 160. When the source drive IC 130 is manufactured as a driving chip, the source drive IC 130 may be packaged in the flexible film 140 in a chip on film COF method or a chip on plastic COP method.

Pads, such as data pads, may be formed in the non-display area of the display panel. Lines connecting the pads with the source drive IC 130 and lines connecting the pads with lines of the circuit board 150 may be formed in the flexible film 140. The flexible film 140 may be attached onto the pads by using an anisotropic conducting film, whereby the pads may be connected with the lines of the flexible film 140.

Referring to FIG. 1, the substrate 110 according to one example may include a display area DA and a non-display area NDA.

The display area DA is an area where an image is displayed, and may be a pixel array area, an active area, a pixel array unit, a display unit, or a screen. For example, the display area DA may be disposed at a central portion of the display panel.

The display area DA according to one example may include gate lines, data lines, pixel power lines, and a plurality of pixels P. Each of the plurality of pixels P may include a plurality of sub-pixels SP that may be defined by gate lines and data lines. Each of the plurality of sub-pixels SP may be defined as the smallest unit area where actual light is emitted.

According to one example, at least four subpixels SP arranged adjacently and configured to emit different colors among a plurality of subpixels SP constitute an one unit pixel P. The one unit pixel may include, but is not limited to, a red subpixel, a white subpixel, a blue subpixel, and a green subpixel.

Each of the plurality of subpixels SP may include a thin film transistor and an organic light-emitting element connected to the thin film transistor. The subpixel may include an organic light-emitting layer (or light-emitting layer) interposed between a first electrode and a second electrode.

The organic light-emitting layer arranged in each of the plurality of subpixels SP can individually emit different color light or commonly emit white light. For example, when the organic light-emitting layer of each of the plurality of sub-pixels SP commonly emits white light, each of the red sub-pixel, the green sub-pixel, and the blue sub-pixel may include a color filter CF (or wavelength conversion member CF) that converts the white light into light of a different color. In this case, the white subpixel according to one example may not have a color filter. The color filter CF according to one example may include a red color filter CF1 (shown in FIG. 2), a blue color filter CF2 (shown in FIG. 2), and a green color filter (shown in FIG. 2).

In the display apparatus 100 according to one embodiment of the present disclosure, an area provided with the red color filter CF1 may be a red subpixel SP1, an area provided with the blue color filter CF2 may be a blue subpixel SP3, an area provided with the green color filter may be a green subpixel SP4, and an area without the color filter may be a white subpixel SP2. In the present disclosure, the red subpixel SP1 may be represented as a first subpixel equipped to emit red light, the blue subpixel SP3 may be represented as a third subpixel equipped to emit blue light, the green subpixel SP4 may be represented as a fourth subpixel equipped to emit green light, and the white subpixel SP2 may be represented as a second subpixel equipped to emit white light.

Each of the subpixels SP supplies a predetermined current to the organic light emitting element in accordance with a data voltage of the data line when a gate signal is input from the gate line by using the thin film transistor. For this reason, the light emitting layer of each of the subpixels may emit light with a predetermined brightness in accordance with the predetermined current.

The display area DA may include a light emission area EA and a non-light emission area NEA. The light emission area EA is the area where light is emitted by the organic light-emitting element layer E. The non-light emission area NEA is the area that does not transmit most of the light incident from the outside.

For example, the non-light emission area NEA may be an area excluding the light emission area EA where light is emitted. In one example, the non-light emission area NEA may include a circuit area CA (shown in FIG. 2). The circuit area CA may include a thin film transistor 112 for driving each of the plurality of subpixels SP (or the organic light emitting element layer E of each of the plurality of subpixels SP).

In the display apparatus 100 according to one embodiment of the present disclosure, the non-light emission area NEA may include a first non-light emission area NEA1 and a second non-light emission area NEA2.

According to one example, the first non-light emission area NEA1 may be provided on the inner side of each of the plurality of sub-pixels SP. For example, as shown in FIG. 2, the inner side of each of the plurality of sub-pixels SP may mean an inner side of the light emission area EA included in one sub-pixel SP. The organic light-emitting element layer E (shown in FIG. 5) may not be arranged in the first non-light emission area NEA1.

According to one example, the second non-light emission area NEA2 may be provided on an outer side of each of the plurality of subpixels SP. For example, as shown in FIG. 2, an outer side of each of the plurality of subpixels SP may mean between the plurality of subpixels SP. Accordingly, the second non-light emission area NEA2 may be distinguished from the first non-light emission area NEA1 which is positioned between the light emission area EA (e.g., the first light emission area EA1 and the second light emission area EA2) included in one subpixel SP. The outer side of each of the plurality of subpixels SP, e.g., the second non-light emission area NEA2, may include a circuit area CA adjacent to the light emission area EA. Additionally, the outer side of each of the plurality of subpixels SP may include an area between the plurality of subpixels SP (e.g., pixel electrodes 114 (shown in FIG. 5) of each of the first subpixel SP1 and the second subpixel SP2) that emit light of different colors.

Additionally, in the non-light emission area NEA, the plurality of pixels P and a plurality of lines for driving each of the plurality of pixels P can be disposed. The plurality of lines, according to one example, can include a plurality of first signal lines and a plurality of second signal lines.

The plurality of first signal lines may be extended in the second direction (X-axis direction). Each of the plurality of first signal lines may include at least one gate line GL (or scan line).

The plurality of second signal lines can extend in the first direction (Y-axis direction). The plurality of second signal lines can intersect with the plurality of first signal lines. Each of the plurality of second signal lines may include a pixel power line EVDD, a plurality of data lines DL, and a reference line RL. The plurality of data lines DL can include a first data line for driving the first sub-pixel SP1, a second data line for driving the second sub-pixel SP2, a third data line for driving the third sub-pixel SP3, and a fourth data line for driving the fourth sub-pixel SP4.

Referring back to FIG. 1, the non-display area NDA is an area on which an image is not displayed, and may be a peripheral circuit area, a signal supply area, an inactive area or a bezel area. The non-display area NDA may be configured to be in the vicinity of the display area DA. That is, the non-display area NDA may be disposed to surround the display area DA.

The display apparatus 100 according to one embodiment of the present disclosure can include a pad portion PA disposed in the non-display area NDA. The pad portion PA can be for driving the plurality of pixels P. For example, the pad portion PA can supply power and/or signals for the plurality of pixels P disposed in the display area DA to output images.

According to one example, the pad portion PA may be placed in the non-display area NDA (or the first non-display area NDA1) above the display area DA based on FIG. 1.

The gate driver GD supplies gate signals to the gate lines in accordance with the gate control signal input from the timing controller 181. The gate driver GD may be formed on one side of the display area DA of the display panel or on the non-display area NDA outside both sides of the display area DA in a gate driver in panel GIP method as shown in FIG. 1.

The plurality of gate drivers GD may be separately disposed on a left side of the display area DA, that is, the second non-display area and a right side of the display area DA, that is, the third non-display area.

According to one example, the plurality of gate drivers GD may be connected to the plurality of pixels P and the plurality of first signal lines for supplying signals to the plurality of pixels P. The plurality of first signal lines may include at least one signal line for supplying a signal for driving the pixel P.

The plurality of second signal lines may be extended in the first direction (Y-axis direction). The plurality of second signal lines may include a pixel power line EVDD and at least one data line DL to supply a data voltage to the pixel P. Each of the plurality of second signal lines may be connected to at least one of a plurality of pads, a pixel power shorting bar, and a common power shorting bar. The pixel power shorting bar and the common power shorting bar can be arranged in a fourth non-display area facing a pad portion PA based on the display area DA.

The pixels P are provided to overlap at least one of the first signal line or the second signal line and emit predetermined light to display an image. The light emission area EA may correspond to an area, which emits light, in the pixel P.

The non-light emission area NEA may refer to an area that is provided in the display area DA and does not emit light, and may be expressed as a dead zone because it does not emit light. The dead zone according to one example may be an area in which a black matrix and/or a bank is provided, but is not limited thereto, and may refer to an area in which light is not emitted.

According to one embodiment of the present disclosure, the display apparatus 100 can improve light efficiency by allowing a size (or area) of the light emission area EA to be expanded (or enlarged) by arranging the repair portion RPP in the first non-light emission area NEA1 which is a dead zone, and a repair process can be performed through the repair portion RPP.

In the display apparatus 100 according to one embodiment of the present disclosure, a repair portion RPP may be placed in a first non-light emission area NEA1. For example, as shown in FIG. 3, a light-emission area EA included in one subpixel SP may include a first light-emission area EA1, a second light-emission area EA2, and a third light-emission area EA3 sequentially connected in a first direction (Y-axis direction) (or downward direction based on FIG. 3) through a first connecting portion CP1 and a second connecting portion CP2. Since the organic light-emitting element layer E is also disposed in each of the first connecting portion CP1 and the second connecting portion CP2, light can be emitted from each of the first connecting portion CP1 and the second connecting portion CP2. Accordingly, the light emission area EA included in one subpixel SP may be the first light-emission area EA1, the first connecting portion CP1, the second light-emission area EA2, the second connecting portion CP2, and the third light-emission area EA3 sequentially connected in the first direction (Y-axis direction) (or downward direction based on FIG. 3).

Meanwhile, the display apparatus 100 according to one embodiment of the present disclosure can prevent the entire light-emission area EA of each subpixel SP from being darkened by foreign substances generated during the manufacturing process. For example, when a foreign substance is attached to one or two of the first light-emission area EA1, the second light-emission area EA2, and the third light-emission area EA3, the first connecting portion CP1 (or the second connecting portion CP2) is cut by a laser apparatus, so that the light-emission area (e.g., the first light-emission area EA1) to which the foreign substance is attached becomes dark, and the remaining light-emission areas (e.g., the second light-emission area EA2 and the third light-emission area EA3) can be driven normally (or slightly darkened).

To this end, the display apparatus 100 according to one embodiment of the present disclosure may be provided such that a width CW (shown in FIG. 2) of the first connecting portion CP1 is narrower than a width EW of the first light-emission area EA1. If the width CW of the first connecting portion CP1 is equal to or wider than the width EW of the first light-emission area EA1, a lines connected to the organic light-emitting element layer E or the circuit area CA may be damaged during a cutting process in which a laser apparatus cuts the first connecting portion CP1. Accordingly, in the display apparatus 100 according to one embodiment of the present disclosure, the width CW (shown in FIG. 2) of the first connecting portion CP1 is provided to be narrower than the width EW of the first light-emission area EA1, so that damage to the lines connected to the organic light-emitting element layer E or the circuit area CA can be prevented during the cutting process of the first connecting portion CP1. For the same reason as above, a width of the second connecting portion CP2 can be provided to be the same as the width of the first connecting portion CP1.

Referring to FIG. 3, the repair portion RPP according to one example may be placed in the first non-light emission area NEA1 provided between the second emission area EA2 and the third emission area EA3. The repair portion RPP is to prevent the entire light emission area EA from becoming dark (or becoming inoperable or unable to emit light) due to a short circuit between lines (or electrodes). Therefore, the repair portion RPP can be placed near the circuit area CA to disconnect a line connected to the circuit area CA (or a thin film transistor 112 of the circuit area CA). Accordingly, the repair portion RPP can be provided in the first non-light emission area NEA1 placed close to the circuit area CA. For example, as shown in FIG. 3, the repair portion RPP may be placed in the first non-light emission area NEA1 provided between the second emission area EA2 and the third emission area EA3. However, the present disclosure is not limited thereto, and depending on a circuit design, the repair portion RPP may be placed in the first non-light emission area NEA1 provided between the first light emission area EA1 and the second light emission area EA2.

In the display apparatus 100 according to one embodiment of the present disclosure, the substrate 110 may further include a data branch line BRL1 and a reference branch line BRL2.

The data branch line BRL1 may be connected to each of the plurality of sub-pixels SP. For example, as shown in FIG. 3, the data branch line BRL1 in the first sub-pixel SP may be electrically connected to the circuit area CA (or thin film transistor 112) and a data line DL (or a first data line DL1) of the first sub-pixel SP. Accordingly, the data branch line BRL1 can transmit a data signal (or data voltage) applied from the data line DL to the circuit area CA (or thin film transistor 112).

The reference branch line BRL2 is spaced apart from the data branch line BRL1 and can be connected to each of the plurality of sub-pixels SP. For example, as shown in FIG. 3, the reference branch line BRL2 in the first sub-pixel SP can be electrically connected to the circuit area CA (or thin film transistor 112) and the reference line RL of the first sub-pixel SP. Accordingly, the reference branch line BRL2 can sense a change in the characteristics of the thin film transistor 112 arranged in the circuit area CA during a sensing driving mode of the pixel P and transmit it to the reference line RL.

Meanwhile, in the display apparatus 100 according to one embodiment of the present disclosure, the repair portion RPP may include a first repair portion RPP1 and a second repair portion RPP2.

According to one example, the first repair portion RPP1 may partially overlap with the data branch line BRL1. The first repair portion RPP1 is for cutting the data branch line BRL1 when a short occurs in the data line DL. For example, the first repair portion RPP1 can cut the data branch line BRL1 by transmitting the laser impulse LS (shown in FIG. 6) received from the laser apparatus to the data branch line BRL1.

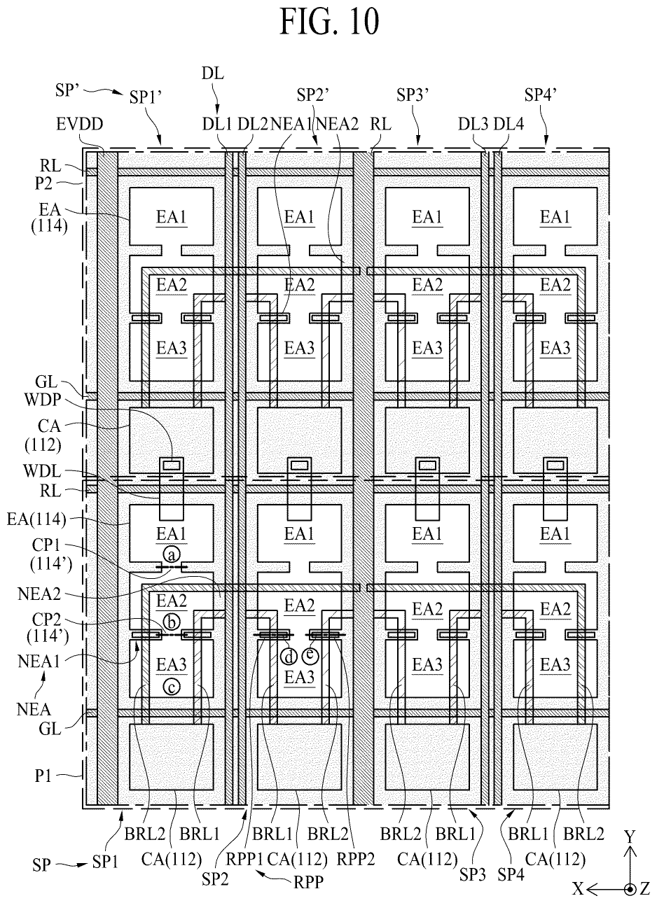

According to one embodiment of the present disclosure, the display apparatus 100 connects a pixel electrode 114 in a subpixel SP where a short circuit occurs and a circuit area CA in another subpixel SP (e.g., a subpixel SP adjacent to an upper side with respect to FIG. 3) through a welding line WDL (shown in FIG. 10) (or a welding process) after the data branch line BRL1 is cut by the first repair portion RPP1, thereby enabling the light-emission area EA of the subpixel SP where a short circuit occurs to be driven together with a light-emission area EA of the another subpixel SP. This will be described later with reference to FIG. 10

The second repair portion RPP2 according to one example may partially overlap the reference branch line BRL2. The second repair portion RPP2 is for cutting the reference branch line BRL2 when a short circuit occurs in the reference line RL. For example, the second repair portion RPP2 may cut the reference branch line BRL2 by transmitting a laser impulse LS received from a laser apparatus to the reference branch line BRL2.

According to one embodiment of the present disclosure, the display apparatus 100 connects a pixel electrode 114 in a subpixel SP where a short circuit occurs and a circuit area CA in another subpixel SP (e.g., a subpixel SP adjacent to an upper side with respect to FIG. 3) through a welding line WDL (shown in FIG. 10) (or a welding process) after the reference branch line BRL2 is cut by the second repair portion RPP2, thereby enabling the light-emission area EA of the subpixel SP where a short circuit occurs to be driven together with a light-emission area EA of the another subpixel SP. This will be described later with reference to FIG. 10.

Therefore, the display apparatus 100 according to one embodiment of the present disclosure can prevent the entire light-emission area EA of each subpixel SP from becoming dark due to a short circuit in the data line DL or the reference line RL.

As shown in FIG. 3, each of the first repair portion RPP1 and the second repair portion RPP2 may be provided in an island shape. Since each of the first repair portion RPP1 and the second repair portion RPP2 receives a laser impulse from a laser apparatus, if each of the first repair portion RPP1 and the second repair portion RPP2 is connected to a different line or electrode, the laser impulse may be transmitted to the different line or electrode and cause damage. Therefore, the display apparatus 100 according to one embodiment of the present disclosure may have a structural feature in which each of the first repair portion RPP1 and the second repair portion RPP2 is provided in an island shape.

Meanwhile, referring to FIG. 3, each of the data branch line BRL1 and the reference branch line BRL2 may partially overlap the light-emission area EA. Accordingly, each of the data branch line BRL1 and the reference branch line BRL2 may be formed of a transparent conductive material (or transparent line). In a bottom emission method, if the data branch line BRL1 and the reference branch line BRL2 are provided as opaque line, the data branch line BRL1 and the reference branch line BRL2 block a light emitted from the organic light-emitting layer 116 and emitted toward the substrate 110, thereby reducing a light efficiency. Therefore, in the display apparatus 100 according to one embodiment of the present disclosure, since each of the data branch line BRL1 and the reference branch line BRL2 is provided as the transparent conductive material (or transparent line), a repair structure can be provided while preventing the reduction in light efficiency.

Hereinafter, with reference to FIGS. 5 to 8, a structure of each of the plurality of sub-pixels SP will be described in detail.

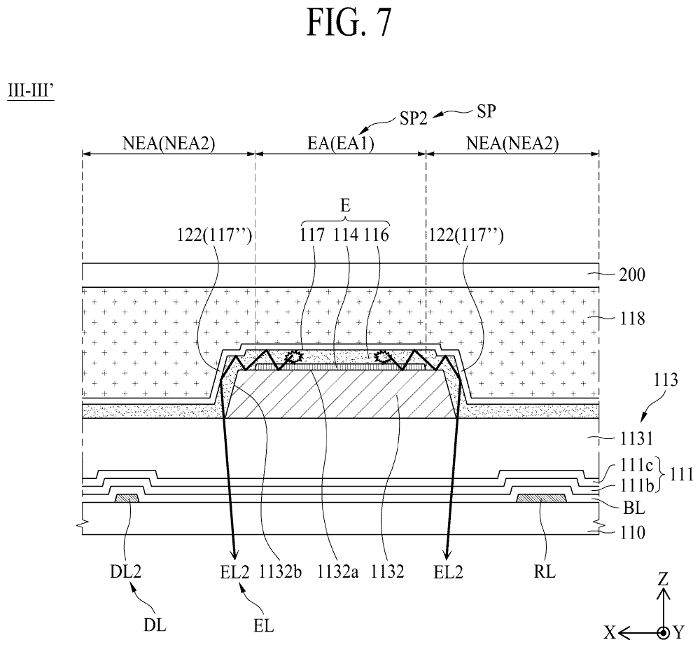

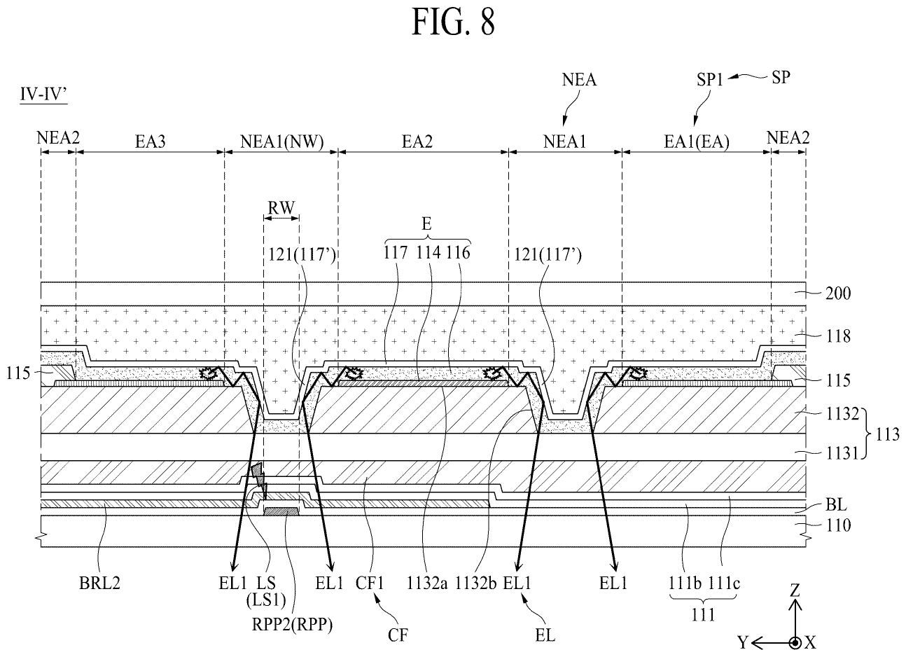

FIG. 5 is a schematic cross-sectional view taken along a line I-I′ (shown in FIG. 3, FIG. 6 is a schematic cross-sectional view taken along a line II-II′ (shown in FIG. 3, FIG. 7 is a schematic cross-sectional view taken along a line III-III′ (shown in FIG. 3, and FIG. 8 is a schematic cross-sectional view taken along a line IV-IV′ (shown in FIG. 3.

Referring to FIG. 5, the display apparatus 100 according to one embodiment of the present disclosure can include a buffer layer BL, a plurality of inorganic films 111, a thin film transistor 112, a color filter CF (shown in FIG. 8), a planarization layer 113, a pixel electrode 114, a bank 115, an organic light emitting layer 116, a reflective electrode 117, and an encapsulation layer 118.

Each of the subpixels SP according to one embodiment may include the plurality of inorganic films 111 provided on an upper surface of the buffer layer BL, including a gate insulating layer 111a, an interlayer insulating layer 111b, and a passivation layer 111c.

Also, each of the subpixels SP may include a color filter CF (shown in FIG. 8) provided on the plurality of inorganic films 111, a planarization layer 113 provided on the color filter CF. The planarization layer 113 may include a first planarization layer 1131 and a second planarization layer 1132. The second planarization layer 1132 may be disposed on the first planarization layer 1131. A pixel electrode 114 may be disposed on the second planarization layer 1132.

Each of the subpixels SP may further include a bank 115 covering one edge of the pixel electrode 114, an organic light-emitting layer 116 on the pixel electrode 114 and the bank 115, and a reflective electrode 117 on the organic light-emitting layer 116. The encapsulation layer 118 may be placed on the reflective electrode 117.

The thin film transistor 112 for driving of subpixel SP may be arranged on the plurality of inorganic films 111. The plurality of inorganic films 111 may also be expressed in terms of a circuit element layer.

The buffer layer BL may be included in the plurality of inorganic films 111 together with the gate insulating layer 111a, the interlayer insulating layer 111b, and the passivation layer 111c. The pixel electrode 114, the organic light emitting layer 116 and the reflective electrode 117 may be included in a light emitting element layer E.

The buffer layer BL may be formed between the substrate 110 and the gate insulating layer 111a to protect the thin film transistor 112 112. The buffer layer BL may be disposed on the entire surface (or front surface) of the substrate 110. The buffer layer BL may serve to block diffusion of a material contained in the substrate 110 into a transistor layer during a high temperature process of a manufacturing process of the thin film transistor 112.

The thin film transistor 112 (or a drive transistor) according to one example may include an active layer 112a, a gate electrode 112b, a source electrode 112c, and a drain electrode 112d.

The active layer 112a may include a channel area, a drain area and a source area, which are formed in a thin film transistor area of a circuit area CA of the subpixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As one example, the gate insulating layer 111a may be formed in an island shape only on the channel area of the active layer 112a or may be formed on the entire front surface of the substrate 110 or buffer layer BL including the active layer 112a.

The gate electrode 112b may be formed on the gate insulating layer 111a to overlap the channel area of the active layer 112a.

The interlayer insulating layer 111b can be formed to partially overlap the gate electrode 112b and the drain area and source area of the active layer 112a. The interlayer insulating layer 111b may be formed over the entire light emission area where light is emitted, as in FIG. 3, in the circuit area CA and the subpixel SP.

The source electrode 112c may be electrically connected to the source area of the active layer 112a through a source contact hole provided in the interlayer insulating layer overlapped with the source area of the active layer 112a.

The drain electrode 112d may be electrically connected to the drain area of the active layer 112a through a drain contact hole provided in the interlayer insulating layer overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode 112b.

Additionally, the thin film transistor provided in the pixel area may have a characteristic in which the threshold voltage is shifted by light. To prevent this, the display panel or the substrate 110 may further include a light-shielding layer LS provided under the active layer 112a of at least one of the thin film transistor 112, a first switching thin film transistor, and a second switching thin film transistor.

The light-shielding layer LS is provided between the substrate 110 and the active layer 112a to block light incident on the active layer 112a through the substrate 110, thereby minimizing changes in the threshold voltage of the transistor caused by external light. In addition, the light shielding layer LS may be provided between the substrate 110 and the active layer 112a to prevent the thin film transistor from being visible to the user.

The passivation layer 111c may be provided on the substrate 110 to cover the pixel area. The passivation layer 111c covers a drain electrode 112d, a source electrode 112c and a gate electrode 112b of the thin film transistor 112, and the buffer layer BL.

The color filter CF (shown in FIG. 8) may be placed on the passivation layer 111c. For example, the color filter CF may be placed between the plurality of inorganic films 111 and the first planarization layer 1131. The color filter CF may include a red color filter CF1 arranged in the red subpixel SP1, a blue color filter CF2 arranged in the blue subpixel SP3, and a green color filter CF3 arranged in the green subpixel SP4. Since the white subpixel SP2 is provided to emit white light, it may not include the color filter.

The planarization layer 113 may be provided on the substrate 110 to cover the passivation layer 111c and the color filter CF. According to one example, the planarization layer 113 may be placed between the substrate 110 and the pixel electrode 114. The planarization layer 113 may be formed in the entire circuit area CA in which the thin film transistor 112 is disposed and the entire light emission area EA. In addition, the planarization layer 113 may be formed in the other non-display area NDA except a pad area PA of the non-display area NDA and the entire display area DA. For example, the planarization layer 113 may include an extension portion (or an enlarged portion) extended or enlarged from the display area DA to the other non-display area NDA except the pad area PA. Therefore, the planarization layer 113 may have a size relatively wider than that of the display area DA.

The planarization layer 113 according to one example may be formed to have a relatively thick thickness, thereby providing a flat surface on the display area DA and the non-display area NDA. For example, the planarization layer 113 may be made of an organic material such as photo acryl, benzocyclobutene, polyimide and fluorine resin.

The planarization layer 113 may include a first planarization layer 1131 and a second planarization layer 1132 disposed on the first planarization layer 1131. The first planarization layer 1131 may be disposed on the substrate 110. The second planarization layer 1132 may be disposed on the first planarization layer 1131. According to one example, the second planarization layer 1132 may be partially disposed between the first planarization layer 1131 and the pixel electrode 114.

The first planarization layer 1131 is provided to cover the passivation layer 111c and the color filter CF, so that it can be formed continuously across the plurality of subpixels SP. In contrast, the second planarization layer 1132 can be formed discontinuously. For example, the second planarization layer 1132 can be formed discontinuously by forming a pattern portion (or first pattern portion) in which the second planarization layer 1132 in the first non-light emission area NEA1 is partially removed. Accordingly, as shown in FIG. 6, a plurality of second planarization layers 1132 may be provided in an island shape on the first planarization layer 1131. However, this is not limited to this, and the second planarization layers 1132 may be formed continuously.

Referring to FIG. 6, an upper surface of the second planarization layer 1132 can be provided flat. Accordingly, the pixel electrode 114 on the second planarization layer 1132 can also be provided flat, and the organic light-emitting layer 116 and the reflective electrode 117 formed thereon can also be provided in a flat form. Since the pixel electrode 114, the organic light-emitting layer 116, and the reflective electrode 117, i.e., the organic light-emitting element layer E, are provided flatly in the light-emission area EA, a thicknesses of the pixel electrode 114, the organic light-emitting layer 116, and the reflective electrode 117 can be formed uniformly within the light-emission area EA. Accordingly, the organic light-emitting layer 116 can emit light uniformly without deviation within the light-emission area EA.

The pixel electrode 114 may be formed on the second planarization layer 1132. As shown in FIG. 5, the pixel electrode 114 may be connected to the drain electrode or source electrode of the thin film transistor through a contact hole penetrating the first planarization layer 1131 and the passivation layer 111c. An edge portions on both sides of the pixel electrode 114 may be covered by the bank 115. Since FIG. 5 is a cross-sectional view in the first direction (Y-axis direction), the bank 115 may be provided to cover an upper and lower edges of the pixel electrode 114 respectively based on a plane (e.g., FIG. 3). In contrast, the bank 115 may not be arranged between the plurality of sub-pixels SP. Accordingly, the display apparatus 100 according to one embodiment of the present disclosure may be provided with a bankless structure in which the bank 115 is not arranged between the plurality of sub-pixels SP arranged in the second direction (X-axis direction).

The pixel electrode 114 may be made of at least one of a transparent metal material or a semi-transmissive metal material.

Because the display apparatus 100 according to an embodiment of the present disclosure is configured as the bottom emission type, the pixel electrode 114 may be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag.

Meanwhile, the material constituting the pixel electrode 114 may include MoTi. The pixel electrode 114 may be a first electrode or an anode electrode.

The bank 115 may be an area, which does not emit light, and can be placed adjacent to the light emission area EA of each of the plurality of sub-pixels SP. For example, the bank 115 may be disposed in the non-light emission area NEA (or the second non-light emission area NEA2 on an upper and lower sides of the pixel electrode 114). The bank 115 may be formed to cover a portion where the edge of the pixel electrode 114. Accordingly, the bank 115 may prevent the pixel electrode 114 and the reflective electrode 117 in the edge of the pixel electrode 114. The exposed portion of the pixel electrode 114 that is not covered by the bank 115 may be included in the light emitting portion (or light emission area EA).

After the bank 115 is formed, an organic light emitting layer 116 may be formed to cover the pixel electrode 114 and the bank 115. Thus, the bank 115 may be partially provided between the pixel electrode 114 and the organic light emitting layer 116. The bank 115 can be expressed in terms of a pixel definition films. The bank 115 according to one example may comprise organic material and/or inorganic material.

The organic light emitting layer 116 may be formed on the pixel electrode 114 and the bank 115. The organic light emitting layer 116 can be placed under the reflective electrode 117. According to one example, the organic light emitting layer 116 may be disposed in the light emission area EA and the non-light emission area NEA (or the first non-light emission area NEA1 and the second non-light emission area NEA2). The organic light emitting layer 116 may be provided between the pixel electrode 114 and the reflective electrode 117. Thus, when a voltage is applied to each of the pixel electrode 114 and the reflective electrode 117, an electric field is formed between the pixel electrode 114 and the reflective electrode 117. Therefore, the organic light emitting layer 116 may emit light. The organic light emitting layer 116 may be formed of a plurality of subpixels SP and a common layer provided on the bank 115.

The organic light emitting layer 116 according to one embodiment may be provided to emit white light. The organic light emitting layer 116 may include a plurality of stacks which emit lights of different colors. For example, the organic light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), an emission layer (EML(B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML(YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack may be arranged all over the plurality of subpixels SP. The organic light emitting layer 116, according to another example, may be provided in a three-stacked structure or a four-stacked structure, depending on the number of stacks stacked.

The reflective electrode 117 may be formed on the organic light emitting layer 116. The reflective electrode 117 may be arranged in the non-display area NDA (or a part of the non-display area NDA) and the display area DA. In the display area DA, the reflective electrode 117 may be arranged in the light emission area EA and the non-light emission area NEA (or the first non-light emission area NEA1 and the second non-light emission area NEA2). That is, the reflective electrode 117 may be arranged to cover the entire display area DA. As a result, the reflective electrode 117 may be arranged to have a size larger than the display area DA and smaller than the substrate 110. Accordingly, the reflective electrode 117 can be placed in the non-display area NDA (or the part of the non-display area NDA) and the display area DA.

The reflective electrode 117 according to one example may include a metal material. The reflective electrode 117 may reflect the light emitted from the organic light emitting layer 116 in the plurality of subpixels SP toward a lower surface of the substrate 110. Therefore, the display apparatus 100 according to one embodiment of the present disclosure may be implemented as a bottom emission type display apparatus.

The display apparatus 100 according to one embodiment of the present disclosure is a bottom emission type and has to reflect light emitted from the light emitting layer 122 toward the substrate 110, and thus the reflective electrode 117 may be made of a metal material having high reflectance. The reflective electrode 117 according to one example may be formed of a metal material having high reflectance such as a silver (Ag), an aluminum (Al), a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The reflective electrode 117 may be expressed as terms such as a second electrode, an opposing electrode and a cathode electrode.

The encapsulation layer 118 is formed on the reflective electrode 117. The encapsulation layer 118 serves to prevent oxygen or moisture from penetrating into the organic light emitting layer 116 and the reflective electrode 117. The encapsulation layer 118 can comprise a plurality of layers including at least one inorganic film and at least one organic film. The encapsulation layer 118 may further contain an absorbent material for absorbing moisture or oxygen to enhance the moisture-proofing effect. For example, the absorbent material may be a getter.

On the other hand, as shown in FIG. 3, the encapsulation layer 118 can be disposed not only in the light emission area EA but also in the non-light emission area NEA. The encapsulation layer 118 can be disposed between the reflective electrode 117 and the opposing substrate 200.

In the display apparatus 100 according to one embodiment of the present disclosure, the first planarization layer 1131 may be provided to have the same refractive index from the second planarization layer 1132. In this case, light emitted from the organic light-emitting layer 116 and directed toward the substrate 110 may not be refracted at a boundary between the first planarization layer 1131 and the second planarization layer 1132 but may be emitted to an outer side of the substrate 110. However, this is not limited thereto, and the first planarization layer 1131 may be provided to have a different refractive index from the second planarization layer 1132. In this case, light emitted from the organic light-emitting layer 116 and directed toward the substrate 110 may be refracted at the boundary between the second planarization layer 1132 and the first planarization layer 1131 and may be emitted to the outer side of the substrate 110. Below, one example is given in which the second planarization layer 1132 has the same refractive index as the first planarization layer 1131.

Referring to FIGS. 6 and 7, the display apparatus 100 according to one embodiment of the present disclosure may further include a first reflective portion 121 and a second reflective portion 122.

Referring to FIG. 6, the first reflective portion 121 may be arranged to be inclined in the first non-light emission area NEA1. According to one example, the first reflective portion 121 may be arranged on the second planarization layer 1132 (or an inclined surface 1132b of the second planarization layer 1132) in the first non-light emission area NEA1. As shown in FIG. 6, since the inclined surface 1132b of the second planarization layer 1132 is arranged to be inclined, the first reflective portion 121 arranged on the inclined surface 1132b of the second planarization layer 1132 may be arranged to be inclined.

The first reflective portion 121 is formed of a material capable of reflecting light, so that light emitted from the light-emission area EA and wave-guided can be reflected toward the light-emitting subpixel SP. The first reflective portion 121 can be formed along a profile of a first pattern portion concavely formed in the first non-light-emission area NEA1. As illustrated in FIG. 6, the first reflective portion 121 is a part of the reflective electrode 117 disposed in the first non-light-emission area NEA1, and thus can be indicated by the drawing reference numeral 117′.

As shown in FIG. 6, the first reflective portion 121 may be arranged obliquely in the first non-light emission area NEA1. Accordingly, the first reflective portion 121 may be expressed in terms of an inner reflective portion and an inner oblique reflective portion located on the inner side of each of the plurality of subpixels SP.

Therefore, the display apparatus 100 according to one embodiment of the present disclosure is provided with the reflective portion (or the first reflective portion 121) arranged in the non-light emission area NEA (or the first non-light emission area NEA1) provided on the inner side of each of the plurality of sub-pixels SP, so that light extraction can be achieved even in the non-light emission area NEA (or the first non-light emission area NEA1), and thus light efficiency can be improved.

Referring to FIG. 7, the second reflective portion 122 according to one example may be arranged at an angle in the second non-light emission area NEA2. The second reflective portion 122 may be arranged at an angle by being arranged on an inclined surface 1132b of the second planarization layer 1132 in the second non-light emission area NEA2. The second reflective portion 122 is formed of a material capable of reflecting light, so that light emitted from the light-emission area EA and wave-guided can be reflected toward the light-emission area EA of the light-emitting subpixel SP. The second reflective portion 122 can be formed along the profile of a pattern portion (or second pattern portion) concavely formed in the second non-light emission area NEA2. As illustrated in FIG. 7, the second reflective portion 122 is a part of the reflective electrode 117 disposed in the second non-light emission area NEA2, and thus can be indicated by the drawing symbol 117″.

Since the second reflective portion 122 is arranged obliquely in the second non-light emission area NEA2, it can be expressed in terms of an outer reflective portion and an outer oblique reflective portion located on the outer side of each of the plurality of subpixels SP.

Therefore, the display apparatus 100 according to one embodiment of the present disclosure is provided with the reflective portion (or the second reflective portion 122) positioned in the non-light emission area NEA (or the second non-light emission area NEA2) provided on the outer side of the plurality of sub-pixels SP, so that light directed toward an adjacent sub-pixel SP can be reflected by the reflective portion (or the second reflective portion 122), thereby preventing color mixing and maximizing light extraction efficiency.

As a result, since the display apparatus 100 according to one embodiment of the present disclosure can extract light even in the non-light-emission area NEA through the reflective portions (or the first reflective portion 121 and the second reflective portion 122) provided on the inner side and outer side of each of the plurality of subpixels SP, the display apparatus can have the same light-emitting efficiency or improve the light-emitting efficiency to a greater extent with lower power compared to a display apparatus having no reflective portions on the inner side and outer side of each of the plurality of subpixels, so that the overall power consumption can be reduced.

Meanwhile, in the display apparatus 100 according to one embodiment of the present disclosure, some of the light emitted from the organic light-emitting layer 116 may be emitted to the outer side of the substrate 110 by the first reflective portion 121 and the second reflective portion 122. Accordingly, the light reflected by each of the first reflective portion 121 and the second reflective portion 122 and emitted toward the substrate 110 may be defined as a reflected light EL.

For example, as shown in FIG. 6, some of the light emitted from the organic light-emitting layer 116 may be reflected by the first reflective portion 121 provided in the first non-light emission area NEA1 and emitted to the outer side of the substrate 110. Accordingly, the reflected light EL reflected and emitted by the first reflective portion 121 in the first non-light emission area NEA1 may be defined as a first reflected light EL1.

In contrast, as shown in FIG. 7, some of the light emitted from the organic light-emitting layer 116 may be reflected by the second reflective portion 122 provided in the second non-light emission area NEA2 and emitted to the outer side of the substrate 110. Accordingly, the reflected light EL reflected by the second reflective portion 122 in the second non-light emission area NEA2 and emitted may be defined as a second reflected light EL2.

As a result, the display apparatus 100 according to one embodiment of the present disclosure can improve light efficiency because light extinguished by the waveguide can be reflected by the first reflective portion 121 in the first non-light emission area NEA1 and emitted as first reflected light EL1, and light extinguished by the waveguide can be reflected by the second reflective portion 122 in the second non-light emission area NEA2 and emitted as second reflected light EL2.

Referring again to FIG. 6, in the display apparatus 100 according to one embodiment of the present disclosure, the data branch line BRL1 may be placed on the first repair portion RPP1.

During a repair process, a laser apparatus can apply a laser impulse LS from the lower portion of the substrate 110 toward the inner side of the substrate 110, for example, the first repair portion RPP1 (or the data branch line BRL1). However, if the first repair portion RPP1 is not present, the laser impulse LS may affect not only the data branch line BRL1 but also the reflective electrode 117 on the data branch line BRL1, thereby causing damage (or cracking) to the reflective electrode 117. Accordingly, the display apparatus 100 according to one embodiment of the present disclosure is provided such that the data branch line BRL1 is arranged on the first repair portion RPP1, so that damage (or cracking) of the reflective electrode 117 is prevented during a repair process using a laser apparatus, while only the data branch line BRL1 can be cut.

For the above reason, the display apparatus 100 according to one embodiment of the present disclosure may be provided such that the reference branch line BRL2 is placed on the second repair portion RPP2.

Meanwhile, each of the data branch line BRL1 and the reference branch line BRL2 may be arranged closer to the substrate 110 than the reflective electrode 117. Therefore, the laser impulse LS by the laser apparatus during the repair process may have a long wavelength. This is because if the laser impulse LS has a short wavelength, the laser impulse LS may penetrate deep into the inner side of the substrate 110 and damage the organic light-emitting element layer E (e.g., the pixel electrode 114). Therefore, in the display apparatus 100 according to one embodiment of the present disclosure, a long-wavelength laser impulse LS is used in the repair process of each of the data branch line BRL1 and the reference branch line BRL2, so that each of the data branch line BRL1 and the reference branch line BRL2 can be cut, while preventing damage to the organic light-emitting element layer E. In the present disclosure, the laser impulse LS using a long wavelength can be defined as a first laser impulse LS1 (shown in FIG. 6).

Meanwhile, a width RW of the repair portion RPP (e.g., a first repair portion RPP1) may be provided narrower than a width NW of the first non-light emission area NEA1. If the width RW of the repair portion RPP (e.g., the first repair portion RPP1) is equal to or wider than the width NW of the first non-light emission area NEA1, the light reflected by the first reflective portion 121 is blocked by the repair portion RPP (e.g., the first repair portion RPP1) and cannot be emitted to the outer side of the substrate 110. Accordingly, the display apparatus 100 according to one embodiment of the present disclosure can have a repair structure while preventing a decrease in light extraction efficiency by having the width RW of the repair portion RPP (e.g., the first repair portion RPP1) narrower than the width NW of the first non-light emission area NEA1.

The display apparatus 100 according to one embodiment of the present disclosure may include a color filter CF provided between the repair portion RPP and the reflective electrode 117. For example, as shown in FIG. 6, a blue color filter CF2 may be disposed between the repair portion RPP and the reflective electrode 117. Accordingly, the blue color filter CF2 may prevent laser impulse LS from reaching the reflective electrode 117 during a repair process. That is, the blue color filter CF2 may have a barrier function that reduces the laser impulse LS.

As shown in FIG. 3, the blue subpixel SP3 in which the blue color filter CF2 is arranged may be arranged adjacent to the white subpixel SP2. Accordingly, when the blue color filter CF2 is formed in the blue subpixel SP3, by also forming the blue color filter CF in the first non-light emission area NEA1 of the white subpixel SP2, the blue color filter CF2 can be easily provided between the repair portion RPP and the reflective electrode 117 without an additional process. Accordingly, the display apparatus 100 according to one embodiment of the present disclosure may have a structural feature in which the blue color filter CF2 is disposed not only in the blue subpixel SP3 but also in the first non-light emission area NEA1 of the white subpixel SP2 (or the first non-light emission area NEA1 provided with the repair portion RPP of the white subpixel SP2).

In the above, the blue color filter CF2 is described as reducing the laser impulse LS, but it is not limited thereto, and a color filter of a different color or a different material can be placed between the repair portion RPP and the reflective electrode 117 if it can reduce (or absorb) the laser impulse LS. For example, a red color filter CF1 or a green color filter CF3 can be placed between the repair portion RPP and the reflective electrode 117. Alternatively, a material forming a bank 115 can be placed between the repair portion RPP and the reflective electrode 117.

Referring again to FIG. 6, in the display apparatus 100 according to one embodiment of the present disclosure, a width CFW of the color filter CF (or blue color filter CF2) provided between the repair portion RPP and the reflective electrode 117 may be provided to be wider than a width RW of the repair portion RPP. As described above, the color filter CF (or blue color filter CF2) is for reducing (or absorbing) the laser impulse LS. Therefore, if the width CFW of the color filter CF (or blue color filter CF2) provided between the repair portion RPP and the reflection electrode 117 is equal to or narrower than the width RW of the repair portion RPP, the laser impulse LS may affect the reflection electrode 117, thereby damaging the reflection electrode 117. Therefore, in the display apparatus 100 according to one embodiment of the present disclosure, the width CFW of the color filter CF (or blue color filter CF2) provided between the repair portion RPP and the reflective electrode 117 is provided to be wider than the width RW of the repair portion RPP, so that damage to the reflective electrode 117 can be prevented during the repair process.

In addition, as shown in FIG. 6, if the width CFW of the color filter CF (or blue color filter CF2) provided between the repair portion RPP and the reflective electrode 117 is wider than the width RW of the repair portion RPP, light reflected by the first reflective part 121 can pass through the blue color filter CF2 and be emitted to the outer side of the substrate 110. Therefore, since the display apparatus 100 according to one embodiment of the present disclosure can emit blue light from the first non-light emission area NEA1 of the white subpixel SP2, the image output from the substrate 110 can have a bluish color tone. Therefore, the display apparatus 100 according to one embodiment of the present disclosure can satisfy the needs of users who want a bluish color tone (or a cool color tone).

According to one embodiment of the present disclosure, the display apparatus 100 includes the red color filter CF1 provided between the repair portion RPP and the reflective electrode 117, so that red light can be emitted from the first non-light emission area NEA1 of the white subpixel SP2, thereby allowing an image output through the substrate 110 to have a yellowish color tone (or a warm color tone). In this case, a user's request for a yellowish color tone (or a warm color tone) can be satisfied.

As a result, the display apparatus 100 according to one embodiment of the present disclosure can implement a color feeling that matches a color coordinates requested by a user by providing one color filter CF among various color filters in the first non-light emission area NEA1 of the white subpixel SP2.

FIG. 8 is a schematic cross-sectional view of line IV-IV′ shown in FIG. 3, showing a cross-sectional view in the first direction (Y-axis direction) of the red subpixel SP1.

The cross-sectional view of the first direction (Y-axis direction) of the red sub-pixel SP1 is identical to the cross-sectional view of the first direction (Y-axis direction) of the white sub-pixel SP2 of FIG. 6 described above, except that the red color filter CF1 is arranged throughout the first light-emission area EA1, the second light-emission area EA2, and the third light-emission area EA3, and the reference branch line BRL2 is arranged on the second repair portion RPP2.

Referring to FIG. 8, in the red subpixel SP1, the red color filter CF1 is placed between the repair portion RPP and the reflective electrode 117, so that red light can be emitted from the first non-light emission area NEA1 of the red subpixel SP1. Accordingly, since the display apparatus 100 according to one embodiment of the present disclosure can emit red light by the first reflective portion 121 and the red color filter CF1 even in the first non-light emission area NEA1 of the red sub-pixel SP1, the light extraction efficiency of the red light may not be reduced even if the first non-light emission area NEA1 is provided the inner side of the red sub-pixel SP1.

Meanwhile, in the red subpixel SP1, the red color filter CF1 is placed between the second repair portion RPP2 and the reflective electrode 117, so that the red color filter CF1 can have a barrier function that reduces laser impulse LS during the repair process of cutting the reference branch line BRL2.

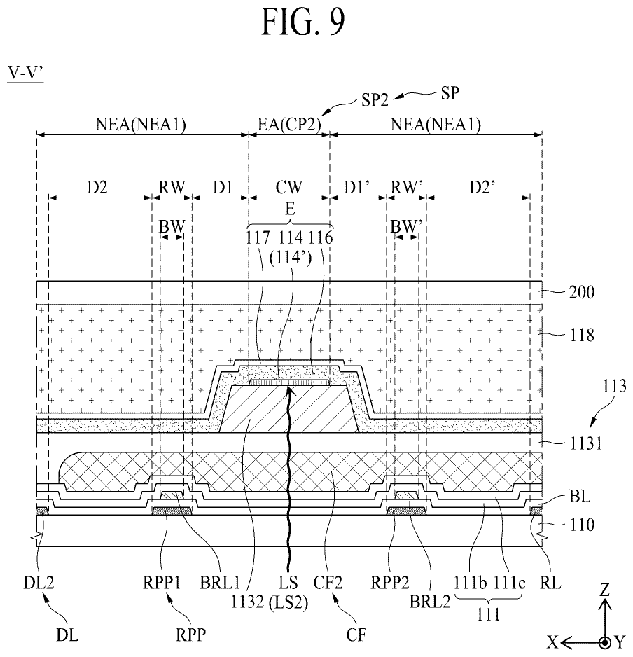

FIG. 9 is a schematic cross-sectional view taken along a line V-V′ (shown in FIG. 3.

Referring to FIG. 9, the display apparatus 100 according to one embodiment of the present disclosure may be provided such that a width RW of the first repair portion RPP1 is wider than a width BW of the data branch line BRL1. If the width RW of the first repair portion RPP1 is equal to or narrower than the width BW of the data branch line BRL1, the first repair portion RPP1 may not sufficiently receive laser impulse from the laser apparatus, and thus the data branch line BRL1 may not be cut. Accordingly, in the display apparatus 100 according to one embodiment of the present disclosure, the width RW of the first repair portion RPP1 is provided to be wider than the width BW of the data branch line BRL1, so that a sufficient laser impulse can be applied to the data branch line BRL1 through the first repair portion RPP1 during the repair process, so that the data branch line BRL1 can be easily cut. For this reason, the display apparatus 100 according to one embodiment of the present disclosure may have a structural feature in which the width RW′ of the second repair portion RPP2 is wider than the width BW′ of the reference branch line BRL2.

Referring to FIG. 9, the second connecting portion CP2 can be positioned between the first repair portion RPP1 and the second repair portion RPP2.

According to one embodiment of the present disclosure, when a foreign substance is attached to one or two of the first light-emission area EA1, the second light-emission area EA2, and the third light-emission area EA3, the first connecting portion CP1 or the second connecting portion CP2 is cut by a laser apparatus, so that the light-emission area (e.g., the first light-emission area EA1) to which the foreign substance is attached becomes dark, and the remaining light-emission areas (e.g., the second light-emission area EA2 and the third light-emission area EA3) can be driven (or slightly darkened) normally. Therefore, in order to prevent a lines around the second connecting portion CP2 (or the first connecting portion CP1) from being damaged during the repair process of cutting the second connecting portion CP2 (or the first connecting portion CP1), a width CW of the second connecting portion CP2 (or the first connecting portion CP1) may be provided to be narrower than a width EW of the light-emission area EA. Therefore, as shown in FIG. 9, the display apparatus 100 according to one embodiment of the present disclosure may have a structural feature in which the second connecting portion CP2 is arranged between the first repair portion RPP1 and the second repair portion RPP2.

Since the second connecting portion CP2 is configured to connect the second light-emission area EA2 and the third light-emission area EA3, it may have the same structure as each of the second light-emission area EA2 and the third light-emission area EA3. Accordingly, as shown in FIG. 9, the second connecting portion CP2 may include an organic light-emitting element layer E provided with a pixel electrode 114, an organic light-emitting layer 116, and a reflective electrode 117. Therefore, the pixel electrode 114 included in the second connecting portion CP2 may be indicated by the drawing symbol 114′. Similarly, the pixel electrode 114 included in the first connecting portion CP1 may also be indicated by the drawing symbol 114′.

Meanwhile, as shown in FIG. 3, the first connecting portion CP1 may be arranged relatively further away from the circuit area CA than the second connecting portion CP2. This is because the first connecting portion CP1 is for connecting the first light-emission area EA1 and the second light-emission area EA2, which are further away from the circuit area CA than the third light-emission area EA3. Accordingly, the first connecting portion CP1 may not be arranged between the first repair portion RPP1 and the second repair portion RPP2.

Referring again to FIG. 9, in the display apparatus 100 according to one embodiment of the present disclosure, the first repair portion RPP1 or the second repair portion RPP2 may be arranged spaced apart from the second connecting portion CP2 by a first distance. For example, the first repair portion RPP1 may be arranged spaced apart from the second connecting portion CP2 by a first distance D1. The second repair portion RPP2 may be arranged spaced apart from the second connecting portion CP2 by a first distance D1′. The first distance D1 (or the first distance D1′) may be a minimum distance that does not affect the first repair portion RPP1 (or the second repair portion RPP2) during a cutting process of the second connecting portion CP2. As shown in FIG. 9, a data branch line BRL1 may be arranged on the first repair portion RPP1, and a reference branch line BRL2 may be arranged on the second repair portion RPP2. Therefore, if the first repair portion RPP1 or the second repair portion RPP2 is arranged to be spaced apart from the second connecting portion CP2 by a distance smaller than the first distance, the laser impulse may also be transmitted to the first repair portion RPP1 or the second repair portion RPP2, thereby damaging the data branch line BRL1 or the reference branch line BRL2. Therefore, the display apparatus 100 according to one embodiment of the present disclosure may have a structural feature in which the first repair portion RPP1 or the second repair portion RPP2 is arranged to be spaced apart from the second connecting portion CP2 by the first distance.

The second connecting portion CP2 can be cut by the laser impulse LS of the laser apparatus. Therefore, when the first repair portion RPP1 (or the second repair portion RPP2) is positioned closer to the second connecting portion CP2 than the first distance D1 (or the first distance D1′), the data branch line BRL1 and/or the reference branch line BRL2 can be cut by being affected by the laser impulse LS. When the data branch line BRL1 and/or the reference branch line BRL2 is cut, the entire light emission area EA connected to the data branch line BRL1 and/or the reference branch line BRL2 cannot be driven.

Therefore, in the display apparatus 100 according to one embodiment of the present disclosure, the first repair portion RPP1 or the second repair portion RPP2 is arranged spaced apart from the second connecting portion CP2 by a first distance in the second direction (X-axis direction), so that damage to the data branch line BRL1 and/or the reference branch line BRL2 can be prevented during a repair process (or cutting process) for the second connecting portion CP2.

Meanwhile, as shown in FIG. 9, the second connecting portion CP2 may be positioned further away from the substrate 110 than the first repair portion RPP1 (or the second repair portion RPP2) in the third direction (Z-axis direction). Accordingly, the laser impulse LS by the laser apparatus during the repair process may have a short wavelength. This is because when the laser impulse LS has a short wavelength, the laser impulse LS may penetrate deeply into the inner side of the substrate 110. Therefore, according to one embodiment of the present disclosure, the display apparatus 100 can cut the second connecting portion CP2 by using a short-wavelength laser impulse LS in the repair process (or cutting process) of the second connecting portion CP2. In the present disclosure, the laser impulse LS using a short wavelength can be defined as a second laser impulse LS2 (shown in FIG. 9).

Referring to FIG. 9, a data line DL (e.g., a second data line DL2) may be arranged to be spaced apart from the first repair portion RPP1 by a second distance D2 in the first non-light-emission area NEA1. The second distance D2 may be a minimum distance that does not affect the data line DL during a cutting process of the data branch line BRL1 using the first repair portion RPP1.

The data branch line BRL1 can be cut by the laser impulse LS of the laser apparatus through the first repair portion RPP1. Therefore, if the data line DL (e.g., the second data line DL2) is arranged closer to the first repair portion RPP1 than the second distance D2, the data line DL can be cut by being affected by the laser impulse LS. If the data line DL is cut, the entire light-emission area EA connected to the cut data line DL cannot be driven.

Therefore, in the display apparatus 100 according to one embodiment of the present disclosure, the data line DL (e.g., the second data line DL2) is arranged to be spaced apart from the first repair portion RPP1 by the second distance D2 in the first non-light-emission area NEA1, so that damage to the data line DL can be prevented during a repair process (or cutting process) of the data branch line BRL1 using the first repair portion RPP1.

For the above reason, the display apparatus 100 according to one embodiment of the present disclosure may be provided so that the reference line RL is arranged to be spaced apart from the second repair portion RPP2 by a second distance D2′ in the first non-light emission area NEA1.

Referring to FIG. 9, the display apparatus 100 according to one embodiment of the present disclosure may be provided such that a color filter CF (e.g., a blue color filter CF2) overlaps the second connecting portion CP2, the first repair portion RPP1, and the second repair portion RPP2. For example, as shown in FIG. 9, the color filter CF (e.g., the blue color filter CF2) may be provided such that it covers the first repair portion RPP1 and the second repair portion RPP2 between the second connecting portion CP2 and the substrate 110.

As described above, the display apparatus 100 according to one embodiment of the present disclosure can prevent the entire light-emission area EA of each subpixel SP from being darkened due to a short circuit between lines included in the substrate 110. For example, when a short circuit occurs between lines, the data branch line BRL1 or the reference branch line BRL2 is cut by the laser impulse LS (or the first laser impulse LS1) transmitted to the repair portion RPP, thereby preventing the entire light-emission area EA from being darkened. In addition, the display apparatus 100 according to one embodiment of the present disclosure can prevent the entire light-emission area EA of each subpixel SP from being darkened by foreign substances generated during a manufacturing process. For example, the first connecting portion CP1 (or the second connecting portion CP2) can be prevented from being darkened by cutting the laser impulse LS (or the second laser impulse LS2) of the laser apparatus, thereby preventing the entire light-emission area EA from being darkened.

Therefore, the display apparatus 100 according to one embodiment of the present disclosure is provided such that the color filter CF (e.g., blue color filter CF2) overlaps the second connecting portion CP2, the first repair portion RPP1, and the second repair portion RPP2, so that the color filter CF (e.g., blue color filter CF2) acts as a barrier that reduces laser impulse LS, thereby preventing the reflective electrode 117 from being damaged (or cut) by the laser impulse LS.

FIG. 10 is a schematic plan view illustrating two pixels of a display apparatus according to one embodiment of the present disclosure.

Referring to FIG. 10, the plurality of pixels (P) may include a first pixel P1 and a second pixel P2. For example, the second pixel P2 may be provided above the first pixel P1 in the first direction (Y-axis direction).

The first pixel P1 may include a first subpixel SP1, a second subpixel SP2, a third subpixel SP3, and a fourth subpixel SP4 sequentially arranged in the second direction (X-axis direction). For example, the first subpixel SP1 may be a red subpixel, the second subpixel SP2 may be a white subpixel, the third subpixel SP3 may be a blue subpixel, and the fourth subpixel SP4 may be a green subpixel.

The second pixel P2 may include another first subpixel SP1′, another second subpixel SP2′, another third subpixel SP3′, and another fourth subpixel SP4′ sequentially arranged in the second direction (X-axis direction). For example, the another first subpixel SP1′ may be a red subpixel, the another second subpixel SP2′ may be a white subpixel, the another third subpixel SP3′ may be a blue subpixel, and the another fourth subpixel SP4′ may be a green subpixel.

Therefore, another first subpixel SP1′ of the second pixel P2 may be provided above the first subpixel SP1 of the first pixel P1 in the first direction (Y-axis direction). Another second subpixel SP2′ of the second pixel P2 may be provided above the second subpixel SP2 of the first pixel P1 in the first direction (Y-axis direction). Another third subpixel SP3′ of the second pixel P2 may be provided above the third subpixel SP3 of the first pixel P1 in the first direction (Y-axis direction). Another fourth sub-pixel SP4′ of the second pixel P2 may be provided above the fourth sub-pixel SP4 of the first pixel P1 in the first direction (Y-axis direction).

As shown in FIG. 10, each of the first to fourth subpixels SP1, SP2, SP3, SP4 of the first pixel P1 may include a first light-emission area EA1, a first connecting portion CP1, a second light-emission area EA2, a second connecting portion CP2, and a third light-emission area EA3. Each of the another first to fourth subpixels SP1′, SP2′, SP3′, SP4′ of the second pixel P2 may be provided with the same structure as each of the first to fourth subpixels SP1, SP2, SP3, SP4 of the first pixel P1.

The first subpixel SP1 of the first pixel P1 may include a pixel electrode 114 partially disposed in the first light emission area EA1. Another first subpixel SP1′ of a second pixel P2 may include a circuit area CA. As shown in FIG. 10, the circuit area CA of another first subpixel SP1′ may be provided between a third light emission area EA3 of another first subpixel SP1′ and the first light emission area EA1 of the first subpixel SP1.

In the display apparatus 100 according to one embodiment of the present disclosure, the substrate 110 may further include a welding line WDL. The welding line WDL is for driving the light-emission area EA of a subpixel SP in which a line short (e.g., a short in a data line or a short in a reference line) has occurred together with a light-emission area EA of another subpixel SP′.

For example, when a short circuit occurs in a data line DL, after the data branch line BRL1 is cut by the first repair portion RPP1, the pixel electrode 114 in the subpixel SP where the short circuit occurred and the circuit area CA (or thin film transistor 112) in another subpixel SP (e.g., a subpixel SP adjacent to an upper side with reference to FIG. 10) may be connected to each other through a welding line WDL. For example, a pixel electrode 114 in a subpixel SP where a short circuit has occurred can be connected to a circuit area CA (or a thin film transistor 112) of another subpixel SP′ (or another subpixel SP′ that is normally driven) by applying a laser impulse to a welding point WDP in a welding line WDL. Accordingly, the welding line WDL can be connected to the pixel electrode 114 of the subpixel SP and the circuit area CA of the another subpixel SP′.

For example, as shown in FIG. 10, a welding line WDL between a first subpixel SP1 and another first subpixel SP1′ can be connected to a pixel electrode 114 of the first subpixel SP1 and a circuit area CA of another first subpixel SP1′. A welding line WDL between a second subpixel SP2 and another second subpixel SP2′ can be connected to a pixel electrode 114 of the second subpixel SP2 and a circuit area CA of another second subpixel SP2′. A welding line WDL between a third sub-pixel SP3 and another third sub-pixel SP3′ can be connected to a pixel electrode 114 of the third sub-pixel SP3 and a circuit area CA of another third sub-pixel SP3′. A welding line WDL between a fourth sub-pixel SP4 and another fourth sub-pixel SP4′ can be connected to a pixel electrode 114 of the fourth sub-pixel SP4 and a circuit area CA of another fourth sub-pixel SP4′.

Meanwhile, as shown in FIG. 10, each of a plurality of welding lines WDL may include a welding point WDP overlapping a circuit area CA of another subpixel SP′. For example, a welding line WDL between a first subpixel SP1 and another first subpixel SP1′ may include a welding point WDP overlapping a circuit area CA of another first subpixel SP1′. A welding line WDL between a second sub-pixel SP2 and another second sub-pixel SP2′ may include a welding point WDP overlapping a circuit area CA of the other second sub-pixel SP2′. A welding line WDL between a third sub-pixel SP3 and another third sub-pixel SP3′ may include a welding point WDP overlapping a circuit area CA of the other third sub-pixel SP3′. A welding line WDL between a fourth sub-pixel SP4 and another fourth sub-pixel SP4′ may include a welding point WDP overlapping a circuit area CA of the other fourth sub-pixel SP1′.

Therefore, in the display apparatus 100 according to one embodiment of the present disclosure, after the data branch line BRL1 or the reference branch line BRL2 of the subpixel SP in which a line short (e.g., a short in the data line or a short in the reference line) has occurred is cut by a laser apparatus, a laser impulse is applied to the welding point WDP so that the pixel electrode 114 of the subpixel SP in which the short has occurred and the thin film transistor 112 of another subpixel SP′ that is normally driven can be connected to each other. Therefore, in the display apparatus 100 according to one embodiment of the present disclosure, the light-emission area EA of the subpixel SP in which the short has occurred can be driven together with the light-emission area EA of the another subpixel SP.

Hereinafter, a repair process of a display apparatus 100 according to an embodiment of the present disclosure will be described with reference to FIG. 10. The repair process of a display apparatus 100 according to an embodiment of the present disclosure may include a first repair process through cutting a connecting portion (e.g., a first connecting portion CP1 and/or a second connecting portion CP2), and a second repair process using a repair portion RPP.

Referring to FIG. 10, the first repair process can be performed in various cases as follows.

First, for example, in the first case where a foreign substance is generated (or attached) at position \textcircled{a} (e.g., the first light-emission area EA1) of the first subpixel SP1, a laser impulse LS is applied to the first connecting portion CP1 to cut the first connecting portion CP1. This can be achieved by the laser apparatus applying a second laser impulse LS2 to the first connecting portion CP1. Accordingly, the second light-emission area EA2, the second connecting portion CP2, and the third light-emission area EA3 of the first subpixel SP1 can be normally driven (or slightly darkened).

Next, for example, in the second case where a foreign substance is generated (or attached) at position \textcircled{b} of the first subpixel SP1 (e.g., the second light-emission area EA2), a laser impulse LS is applied to each of the first connecting portion CP1 and the second connecting portion CP2 to cut the first connecting portion CP1 and the second connecting portion CP2. This can be achieved by the laser apparatus applying the second laser impulse LS2 to each of the first connecting portion CP1 and the second connecting portion CP2.

Next, a laser impulse is applied to a welding point WDP overlapping a circuit area CA of another first subpixel SP1′ to connect a pixel electrode 114 in a first light-emission area EA1 of the first subpixel SP1 and a thin film transistor 112 in a circuit area CA of another first subpixel SP1′. Accordingly, the first light-emission area EA1 of the first subpixel SP1 can be driven together with the light-emission area EA of the another first subpixel SP1′. Therefore, the first light-emission area EA1 of the first subpixel SP1 can be normally driven (or slightly darkened).

Next, in the third case where a foreign substance is generated (or attached) at the \textcircled{c} position (e.g., the third light-emission area EA3) of the first subpixel SP1, a laser impulse LS is applied to the second connecting portion CP2 to cut the second connecting portion CP2. This can be achieved by the laser apparatus applying the second laser impulse LS2 to the second connecting portion CP2.

Next, a laser beam is applied to a welding point WDP overlapping a circuit area CA of another first subpixel SP1′ to connect a pixel electrode 114 in a first light-emission area EA1 of the first subpixel SP1 and a thin film transistor 112 in a circuit area CA of another first subpixel SP1′. The pixel electrode 114 in the second light-emission area EA2 of the first subpixel SP1 can be connected to the pixel electrode 114 in the first light-emission area EA1 of the first subpixel SP1 through the pixel electrode 114 in the first connecting portion CP1 of the first subpixel SP1. Accordingly, the first light-emission area EA1, the first connecting portion CP1, and the second light-emission area EA2 of the first subpixel SP1 can be driven together with the light-emission area EA of another first subpixel SP1′.

Therefore, in the display apparatus 100 according to one embodiment of the present disclosure, the first repair process is performed in the first to third cases as described above, thereby preventing the entire light-emission area EA of each subpixel SP from being darkened by foreign substances generated during the manufacturing process.

Referring again to FIG. 10, the second repair process can be performed in various cases as follows.

First, in the fourth case where a short circuit occurs in the data line DL (e.g., the second data line DL2) of the second subpixel SP2, a laser impulse LS is applied to position \textcircled{d} (e.g., the first repair portion RPP1 to cut the data branch line BRL1. This can be achieved by the laser apparatus applying the first laser impulse LS1 to the first repair portion RPP1.

Next, a laser impulse is applied to a welding point WDP overlapping a circuit area CA of another second subpixel SP2′ to connect a pixel electrode 114 in a first light-emission area EA1 of the second subpixel SP2 and a thin film transistor 112 in a circuit area CA of another second subpixel SP2′. The pixel electrode 114 in the second light-emission area EA2 of the second subpixel SP2 can be connected to the pixel electrode 114 in the first light-emission area EA1 of the second subpixel SP2 via the pixel electrode 114 in the first connecting portion CP1 of the second subpixel SP2, and the pixel electrode 114 in the third light-emission area EA3 of the second subpixel SP2 can be connected to the pixel electrode 114 in the second light-emission area EA2 of the second subpixel SP2 via the pixel electrode 114 in the second connecting portion CP2 of the second subpixel SP2. Accordingly, the first light-emission area EA1, the first connecting portion CP1, the second light-emission area EA2, the second connecting portion CP2, and the third light-emission area EA3 of the second sub-pixel SP2 can be driven together with the light-emission area EA of another second sub-pixel SP2′.

Next, for example, in the fifth case where a short circuit occurs in the reference line RL, a laser impulse LS is applied to the position \textcircled{e} (e.g., the second repair portion (RPP2)) to cut the reference branch line BRL2. This can be achieved by the laser apparatus applying the first laser impulse LS1 to the second repair portion RPP2.

Next, a laser impulse is applied to a welding point WDP overlapping a circuit area CA of another second subpixel SP2′ to connect a pixel electrode 114 in a first light-emission area EA1 of the second subpixel SP2 and a thin film transistor 112 in a circuit area CA of another second subpixel SP2′. The pixel electrode 114 in the second light-emission area EA2 of the second subpixel SP2 can be connected to the pixel electrode 114 in the first light-emission area EA1 of the second subpixel SP2 via the pixel electrode 114 in the first connecting portion CP1 of the second subpixel SP2, and the pixel electrode 114 in the third light-emission area EA3 of the second subpixel SP2 can be connected to the pixel electrode 114 in the second light-emission area EA2 of the second subpixel SP2 via the pixel electrode 114 in the second connecting portion CP2 of the second subpixel SP2. Accordingly, the first light-emission area EA1, the first connecting portion CP1, the second light-emission area EA2, the second connecting portion CP2, and the third light-emission area EA3 of the second sub-pixel SP2 can be driven together with the light-emission area EA of another second sub-pixel SP2′.

Therefore, in the display apparatus 100 according to one embodiment of the present disclosure, the second repair process is performed in the fourth and fifth cases described above, thereby preventing the entire light-emission area EA of each subpixel SP from becoming dark due to a short circuit between electrodes (or lines).

Meanwhile, in the above, it has been described that a welding process is performed to connect a pixel electrode 114 in a first light-emission area EA1 of a second subpixel SP2 where a foreign substance is generated (or attached) by applying laser impulse to a welding point WDP in the second repair process and a thin film transistor 112 in a circuit area CA of another second subpixel SP2′, but it is not necessarily limited thereto.

The display apparatus 100 according to one embodiment of the present disclosure may not be provided with a welding line WDL including a welding point WDP for expanding the light-emission area EA (or aperture ratio) of each of a plurality of subpixels SP. In this case, a weak darkening process may be performed in which only the light-emission area where a foreign substance has occurred is darkened by cutting the first connecting portion CP1 or the second connecting portion CP2 and the remaining light-emission areas are operated normally. When the weak darkening process is performed, some light-emission areas of one subpixel cannot be driven, so a current density of the remaining light-emission areas that are normally driven may increase. Therefore, a compensation process may be additionally performed in which a reduced data voltage is supplied to the subpixel SP on which the weak darkening process is performed compared to the subpixel SP that is normally driven.

Embodiments of the present disclosure have been described in more detail with reference to the accompanying drawings, but the present disclosure is not necessarily limited to these embodiments and may be practiced in various modifications without departing from the technical ideas of the present disclosure. Accordingly, the embodiments disclosed herein are intended to illustrate, not limit, the technical ideas of the present disclosure, and the scope of the technical ideas of the present disclosure is not limited by these embodiments. Therefore, the embodiments described above are exemplary in all respects and should be understood as non-limiting. All technical ideas within the scope of protection of this disclosure should be construed to be included within the scope of the claims of this disclosure.

The display apparatus according to the present disclosure can expand the size (or area) of the light-emission area by having the repair portion disposed in a non-light-emission area (or a first non-light emission area) provided on an inside of each of a plurality of sub-pixels.

The display apparatus according to the present disclosure can have improved light efficiency due to expansion of the size (or area) of the light-light emission area.

The display apparatus according to the present disclosure is provided with the reflective portion (or the first reflective portion) arranged in the non-light emission area (or the first non-light emission area) provided on the inner side of each of the plurality of subpixels, so that the light extraction efficiency of light emitted from the light-emitting element layer can be improved.

The display apparatus according to the present disclosure is provided with the reflective portion (or the second reflective portion) arranged in the non-light emission area (or the second non-light emission area) provided on the outer side of the plurality of sub-pixels, so that the reflective portion (or the second reflective portion) can reflect light directed toward an adjacent sub-pixel, thereby maximizing light extraction efficiency.

In some embodiments, each subpixel within the display area may include a plurality of light emission areas. For example, a first light emission area EA1 and a second light emission area EA2 may be arranged adjacent to one another within a single subpixel. A connecting portion (e.g., CP1, CP2) may be disposed between the first and second light emission areas and may electrically or structurally link the two. In a plan view, the connecting portion may appear as a narrower region connecting broader emission zones. A first non-light emission area NEA1 may extend into the space between the first light emission area EA1 and the second light emission area EA2, and may be recessed or indented relative to the peripheries of those emission areas when viewed from above (e.g., top view or plan view). In such a layout, the first non-light emission area NEA1 may be at least partially surrounded by the first and second light emission areas and the connecting portion in the same planar view. A repair portion RPP may be disposed within the first non-light emission area NEA1 to facilitate electrical isolation or repair.

Each subpixel may include a stacked structure formed on a substrate, including a planarization layer, a pixel electrode disposed on the planarization layer, an organic light-emitting layer disposed on the pixel electrode, and a reflective electrode disposed over the organic light-emitting layer. In some embodiments, the reflective electrode may extend across the emission areas and the non-light emission areas without interruption (e.g., extend continuously and contiguously). A first reflective portion 121 of the reflective electrode may be disposed on an inclined surface of the planarization layer in the first non-light emission area. The inclination may be configured to redirect light emitted by the adjacent emission areas toward the substrate, increasing light extraction efficiency. A second non-light emission area may be disposed between adjacent subpixels and may be connected to the first non-light emission area. A second reflective portion 122 of the reflective electrode may be disposed on an inclined surface of the second non-light emission area and may be similarly arranged to direct light toward the substrate.

In certain embodiments, the reflective electrode may be formed as a continuous and contiguous film extending across the first and second light emission areas, the first non-light emission area, and the second non-light emission area. This continuous structure may simplify fabrication and enhance optical uniformity. A color filter CF may be disposed above the repair portion and between the repair portion and the reflective electrode. The color filter CF may laterally extend beyond the boundaries of the repair portion and may provide thermal or optical shielding during laser repair. For example, the color filter CF may be configured to absorb laser energy used to disconnect a short circuit between a data branch line and a reference branch line. The data branch line and reference branch line may be spaced apart and routed into each subpixel, where they may overlap respective first and second repair portions located in the first non-light emission area.

In some configurations, the first repair portion RPP1 may at least partially overlap the data branch line, while the second repair portion RPP2 may at least partially overlap the reference branch line, as seen in a plan view. These overlapping regions may be designed to serve as laser access points for isolating short circuits. In addition, to preserve electrical continuity after disconnection, a welding line WDL may be formed between a pixel electrode in a first subpixel and a circuit area in a second subpixel. The circuit area may include a thin film transistor or similar drive component. The welding line may include a welding point, which may be disposed near the circuit area and may overlap a boundary of the circuit area in plan view (see FIG. 10). The welding point may serve as the location for establishing an electrical bridge between the subpixels during post-fabrication repair.

Since the display apparatus according to the present disclosure can extract light even in the non-light emission area through the reflective portions (or the first reflective portion and the second reflective portion) provided on the inner and outer sides of each of the plurality of subpixels, the display apparatus can have the same luminous efficiency or can have the luminous efficiency improved to a higher degree even with lower power compared to a display apparatus having no reflective portions on the inner and outer sides of each of the plurality of subpixels, so that the overall power consumption can be reduced.

The effects to be obtained from the present disclosure are not limited to those mentioned above, and other effects not mentioned will be apparent to one of ordinary skill in the art from the description.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate including a plurality of pixels having a plurality of subpixels;
a first non-light emission area provided on the substrate and located inside each of the plurality of subpixels;
a second non-light emission area connected to the first non-light emission area and located between the plurality of subpixels;
a light-emission area adjacent to each of the first non-light emission area and the second non-light emission area; and
a repair portion disposed in the first non-light emission area.

2. The display apparatus of claim 1, wherein each of the light-emission area of the plurality of subpixels includes:
a first light emission area;
a first connecting portion;
a second light emission area spaced apart from the first light emission area and connected to the first light emission area through the first connecting portion;
a second connecting portion;
a third light emission area spaced apart from the second light emission area and connected to the second light emission area through the second connecting portion, and
wherein the first non-light emission area is arranged between the first light emission area and the second light emission area, and between the second light emission area and the third light emission area.

3. The display apparatus of claim 2, wherein the repair portion is arranged in the first non-light emission area provided between the second light emission area and the third light emission area.

4. The display apparatus of claim 2, wherein a width of the first connecting portion is narrower than a width of the first light-emission area in a plan view.

5. The display apparatus of claim 2, wherein the substrate comprises:
a data branch line connected to each of the plurality of sub-pixels; and
a reference branch line spaced apart from the data branch line and connected to each of the plurality of sub-pixels; and
wherein the repair portion comprises:
a first repair portion partially overlapping the data branch line; and
a second repair portion partially overlapping the reference branch line.

6. The display apparatus of claim 5, wherein the data branch line and the reference branch line each partially overlap the light-emission area, and the data branch line and the reference branch line each are made of a transparent conductive material.

7. The display apparatus of claim 5, wherein the data branch line is disposed on the first repair portion, and the reference branch line is disposed on the second repair portion.

8. The display apparatus of claim 7, wherein a width of the first repair portion is wider than a width of the data branch line, and a width of the second repair portion is wider than a width of the reference branch line.

9. The display apparatus of claim 1, further comprising:
a first planarization layer disposed on the substrate;
a second planarization layer disposed on the first planarization layer and having the same refractive index as the first planarization layer;
a first reflective portion disposed on the second planarization layer and arranged obliquely with respect to the first non-light emission area; and
a second reflective portion disposed obliquely with respect to the second non-light emission area.

10. The display apparatus of claim 9, wherein each of the plurality of subpixels includes:
a pixel electrode disposed on the second planarization layer;
an organic light-emitting layer on the pixel electrode; and
a reflective electrode on the organic light-emitting layer,
wherein the first reflective portion and the second reflective portion are a part of the reflective electrode.

11. The display apparatus of claim 1, wherein a width of the repair portion is narrower than a width of the first non-light emission area.

12. The display apparatus of claim 10, further includes a color filter provided between the repair portion and the reflective electrode.

13. The display apparatus of claim 12, wherein the color filter has a width greater than that of the repair portion.

14. The display apparatus of claim 5, wherein the second connecting portion is arranged between the first repair portion and the second repair portion.

15. The display apparatus of claim 5, wherein the first repair portion or the second repair portion is arranged spaced apart from the second connecting portion by a first distance.

16. The display apparatus of claim 5, wherein the substrate further includes a data line electrically connected to the data branch line, and
wherein the data line is arranged in the first non-light emission area and spaced apart from the first repair portion by a second distance.

17. The display apparatus of claim 5, further includes a color filter overlapping the second connecting portion, the first repair portion, and the second repair portion.

18. The display apparatus of claim 17, wherein the color filter covers the first repair portion and the second repair portion between the second connecting portion and the substrate.

19. The display apparatus of claim 2, wherein the plurality of pixels include a first pixel and a second pixel located above the first pixel in a first direction,
wherein the first pixel comprises a first subpixel,
wherein the second pixel comprises another first subpixel located above the first subpixel of the first pixel in the first direction,
wherein the first subpixel comprises a pixel electrode partially arranged in the first light-emission area,
wherein the another first subpixel comprises a circuit area provided between the third light-emission area and the first light-emission area of the first subpixel, and
wherein the substrate further comprises a welding line connected to the pixel electrode of the first subpixel and the circuit area of the another first subpixel.

20. The display apparatus of claim 19, wherein the welding line includes a welding point overlapping the circuit area of the another first subpixel.
